(19) United States
(12) Patent Application Publication
(10) Pub. No.: US 2006/0049839 A1
(43) Pub. Date: Mar. 9, 2006

(54) DYNAMIC SIGNAL INJECTION MICROSCOPY

(75) Inventor: Robert A. Falk, Newcastle, WA (US)

Correspondence Address: BLACK LOWE & GRAHAM, PLLC, 701 FIFTH AVENUE, SUITE 4800, SEATTLE, WA, 98104, US

(73) Assignee: OPTOMETRIX, INC., Renton, WA (US)

(21) Appl. No.: 11/161,814

(22) Filed: Aug. 17, 2005

Related U.S. Application Data
(60) Provisional application No. 60/602,802, filed on Aug. 18, 2004.

(51) Int. Cl. G01R 31/302

(52) U.S. Cl. 324/752

(57) ABSTRACT

Methods and system for sensing dynamic failures in an electronic circuit. An exemplary system includes a drive source, a radiant energy source, and a signal comparator. The drive source supplies a dynamic input signal to the electronic circuit, thereby causing the electronic circuit to output a signal. The radiant energy source generates and directs radiant energy at the electronic circuit and thus induces localized changes in the output signal of the electronic circuit. The signal comparator compares the output signal to an expected output signal, thereby producing a comparison signal proportional to the match between the input and output signals. A data processing device generates an image based on the comparison signal and an image based on a reflection signal. A display device displays at least a portion of the generated images simultaneously.

### CROSS-REFERENCE TO RELATED APPLICATIONS

This is application claims the benefit of U.S. Provisional Application Ser. No. 60/602,802 filed Aug. 18, 2004, which is hereby incorporated by reference.

### FIELD OF THE INVENTION

The present invention relates to laser scanning systems. Specifically, it describes methods and techniques for inducing changes in electronic circuits with the scanning laser and then sensing the changes in the dynamic behavior of the circuits. This basic method and technique can be applied to scanning imaging systems that utilize both optical and non-optical sources, e.g. electron beam and acoustic sources.

### BACKGROUND OF THE INVENTION

Cole, et al. (U.S. Pat. Nos. 5,430,305 and 6,078,183) showed that laser beams can be used to induce electrical changes in electronic circuits, specifically integrated circuits. These changes can be induced through heating of circuit components by the laser and through photocarrier generation in the integrated circuit. Laser wavelength with respect to the semiconductor bandgap determines which of the two effects dominates.

The efforts of Cole, et al. focused on sensing the changes in the current draw of the electronic circuit while it was scanned by the laser. Basically, the laser modulates the impedance of the overall circuit, which can be sensed with appropriate impedance sensing means. These techniques, often referred to as LIVA and TIVA, are capable of locating static shorts and opens in circuits. Work in this area was also performed by Nikawa (U.S. Pat. No. 5,804,980) using the terminology OBRICH.

There are additional classes of circuit failures that do not reveal themselves as static failures. For example, time delays or slow rise times in digital circuits can cause timing failures as the operating frequency is increased. Methods for location of dynamic failures were first explored by Burns, et al. (Reliability/Design Assessment by Internal-Node Timing-Margin Analysis Using Laser Photocurrent-Injection, D. J. Burns, M. T. Pronobis, C. A. Eldering, and R. J. Hillman, Proceedings IEEE/IRPS, 76-82 [1984] and U.S. Pat. No. 4,498,587) and later by Bruce, et al. (U.S. Pat. No. 6,483,326). All of these methods are highly related, differences only occurring in choice of laser wavelength for photo carrier creating versus heating as an example. Further, the methods are specific to digital circuitry.

These dynamic techniques are characterized by two processes:
1) The digital circuit is connected to a test circuit or tester that indicates if the digital circuit is producing a correct digital result, pass/fail. Specifically, a digital tester inputs a digital data block(s) or test pattern and determines that the correct output data block results. A pass/fail signal is indicated.
2) The test circuit is operated in a condition of high temperature or clock speed while the laser is slowly scanned over the circuit. Timing changes induced by the laser can cause the pass/fail condition to shift, indicating a failure location site. There are several difficulties with this approach to localizing dynamic failures:
1) The output signal is strictly digital, pass/fail. There is no information about the relative “strength” of the failure. This issue is particularly problematical when multiple failure sites are observed, specifically which is the critical site?
2) The test pattern must pass through each location on the circuit as the laser passes over that location and only then can a pass/fail determination be made. It is unknown which part of the test pattern causes the pass/fail condition to occur, so all parts must be tried for each laser position. This process can be slow, sometimes taking hours and days.
3) The critical operating condition of temperature or clock speed that lies on the border between pass/fail must be determined. If chosen poorly, the entire test will be wasted.

Therefore, there exists a need for techniques for measuring dynamic failures in both analog and digital circuits.

### BRIEF SUMMARY OF THE INVENTION

The present invention provides methods and system for sensing dynamic failures in an electronic circuit. An exemplary system includes a drive source, a radiant energy source, and a signal comparator. The drive source supplies a dynamic input signal to the electronic circuit, thereby causing the electronic circuit to output a signal. The radiant energy source generates and directs radiant energy at the electronic circuit and thus induces localized changes in the output signal of the electronic circuit. The signal comparator compares the output signal to an expected output signal, thereby producing a comparison signal proportional to the match between the input and output signals.

In one aspect of the invention, the system may also include a data processing device that generates an image based on the comparison signal and a display device that displays the generated image.

In another aspect of the invention, the system may also include a sensor that produces a reflection signal based on a reflection of the directed radiant energy. The data processing device generates an image based on the reflection signal and the display device displays the reflection signal image. The data processing device extracts one or more portions of the comparison signal image and superimposes the extracted one or more portions on the reflection signal image based on location information associated with the reflection signal image and the comparison signal image.

The comparison signal indicates a measure of quality of the electronic circuit.

### BRIEF DESCRIPTION OF THE SEVERAL VIEWS OF THE DRAWING

The preferred and alternative embodiments of the present invention are described in detail below with reference to the following drawings.

FIG. 1 shows an overview of the invention;

FIGS. 2A and 2B show correct and failure data for a digital circuit;

FIG. 3 shows an example in which the signal comparator is a phase sensor;

FIGS. 4A and 4B show images/maps obtained from the implementation shown in FIG. 3; and

FIG. 5 shows an example in which the signal comparator is a harmonic power detector.

### DETAILED DESCRIPTION OF THE INVENTION

The current invention will first be described as a general signal comparison instrument. Specific examples will follow.

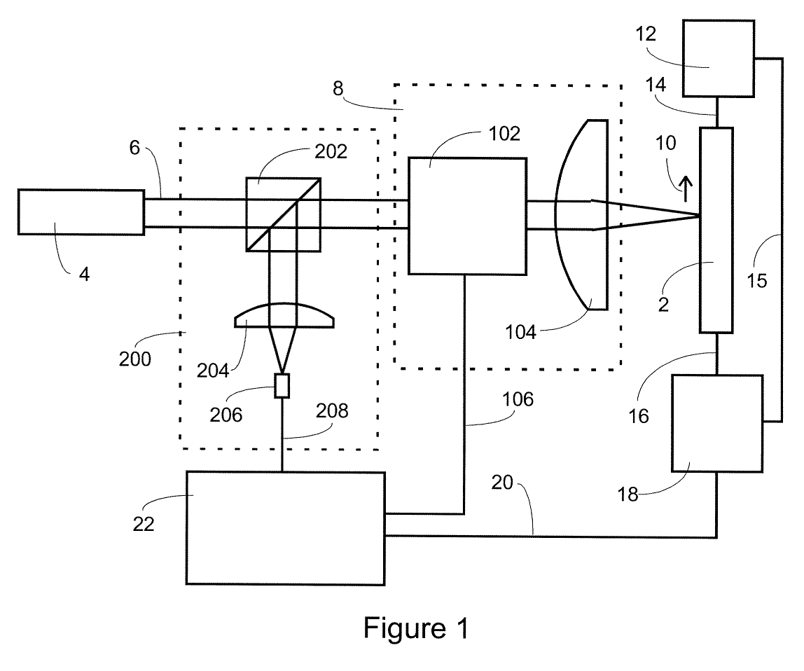

FIG. 1 shows the general components of the invention (device 1) as well as a specific implementation as a laser scanning or confocal imaging system. The device 1 senses properties of a test structure 2. The test structure 2 is typically an integrated circuit, but could also be a printed circuit board or other electronic circuit/device. The goal of the invention in FIG. 1 is to modulate the electrical properties of the test structure 2 and then extract an image relating to its dynamic properties.

A radiant energy source 4 is utilized to excite the test structure 2. There are many options for the radiant energy source 4, including but not limited to:
Optical, e.g. a laser
Electron beam
Ion beam
Acoustic

The radiant energy source 4 may produce an excitement in the test structure 2 via a number of means, including but not limited to:
Heating
Photo carrier production
Direct electron injection
Ionization

A radiant energy beam 6 produced by the radiant energy source 4 is directed towards a scanning device 8. In the case where the beam 6 is an optical radiant energy beam, the scanner device 8 may include a scanning mirror assembly 102 and a lens 104 for focusing the radiant energy beam 6 onto the test structure 2. A control line 106 is also shown. The control line 106 is utilized to synchronize the position of the scanner device 8 with the other data acquisition processes described below. In the case where the beam 6 is an electron or ion beams, the scanning device may include equivalent electromagnetic beam deflectors and focusing elements. The scanning device 8 directs the radiant energy beam 6 on to the test structure 2 and scans the beam 6 across the test structure 2. Any assembly that produces this result is acceptable. Shown in FIG. 1 is an arrow 10 indicating a possible upwards scanning motion of the radiant energy beam 6. Note that the test structure 2 may also be moved to supply the scanning function.

A drive source 12 supplies a drive signal 14 and a reference signal 15. The drive signal 14 is used as a dynamic operational input to the test structure 2. The drive signal 14 is any modulated signal such as a digital clock, a digital pattern, a sine wave, etc. that is needed to place the test object 2 into a desired dynamic mode and in turn induces the test object 2 to produce a test signal 16. The drive signal 14, the reference signal 15, and the test signal 16 can include single or multiple lines with any combination of digital and analog signals.

The test signal 16 is feed into a signal comparator 18. The reference signal 15 is also shown being feed into the signal comparator 18, however, it is not necessary in all implementations of the current invention. The signal comparator 18 compares the quality of the test signal 16 to a perfect test signal. A comparison signal 20 is the result of the comparison of the test signal 16 with this perfect test signal. The comparison signal 20 is thereby a measurement of the quality of the test signal 16.

Once produced, the comparison signal 20 is sent to a processing and display device 22. For example, the processing and display device 22 may be a general purpose computer and a monitor. The comparison signal 20 is collected as a function of position of the radiant energy beam 6 on the test structure 2 as determined by the control line 106 and then is displayed as an image or map as a function of the position.

In one embodiment, the device 1 is a laser scanning or confocal imaging system and the radiant energy source 4 is a laser. The beam from the laser propagates to the scanning device 8. The scanning device 8 includes a scanning mirror assembly 102 coupled with a focusing lens 104. The laser beam passes through the scanning mirror assembly 102, which deflects the laser beam at an angle versus time. The first lens 104 transforms the angular scan into a position scan on the test structure 2. The first lens 104 also focuses the laser beam onto the test structure 2.

A sufficiently high power laser beam can heat the test structure 2 by 10's to hundreds of degrees centigrade. This temperature rise induces changes in the impedance of components within the test structure 2. When the test structure 2 is a semiconductor device additional impedance changes can occur due to production of photocarriers, however, the laser wavelength must be short compared to the semiconductor band gap for photocarrier production to occur. It is via these impedance changes that the laser beam induces changes in the test signal 18.

An additional feature of the laser scanning embodiment is the ability to collect a reflected light image simultaneously with the thermal-acoustic image through use of a reflected light sensor 200. The radiant energy beam 6, when in the form of a laser beam, is reflected back from the test structure 2 and recollected by the focus lens 104. The reflected beam is redirected by a beam splitter 202 in the sensor 200 towards a detector lens 204, which focuses the reflected beam onto a detector 206. Note that the detector lens 204 is not strictly necessary in all laser-scanning configurations. The detector 206 produces a reflected light signal 208 that is proportional to the amount of the laser beam reflected back from the test structure. The reflected light signal is directed to the processing and display means 22 where an image of the test structure can be displayed. Thus, the reflected light sensor 200 produces a standard confocal image of the test structure 2 that is pixel-by-pixel correlated with the image/map of the comparison signal 20. This confocal image can be used in an overlay process to correlate the location of a specific comparison signal 20 to a physical location on the test structure 2.

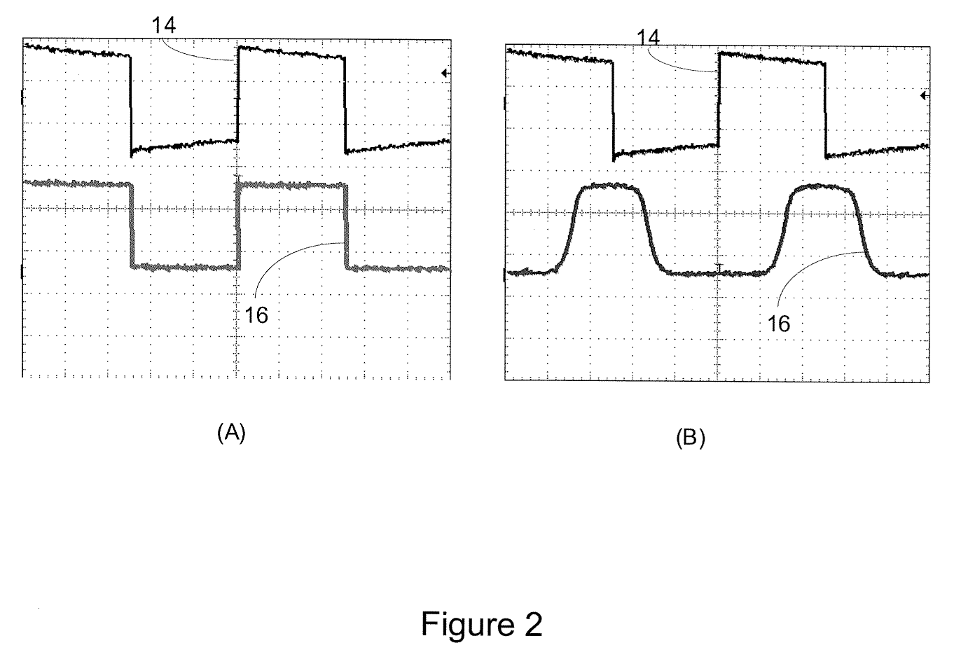

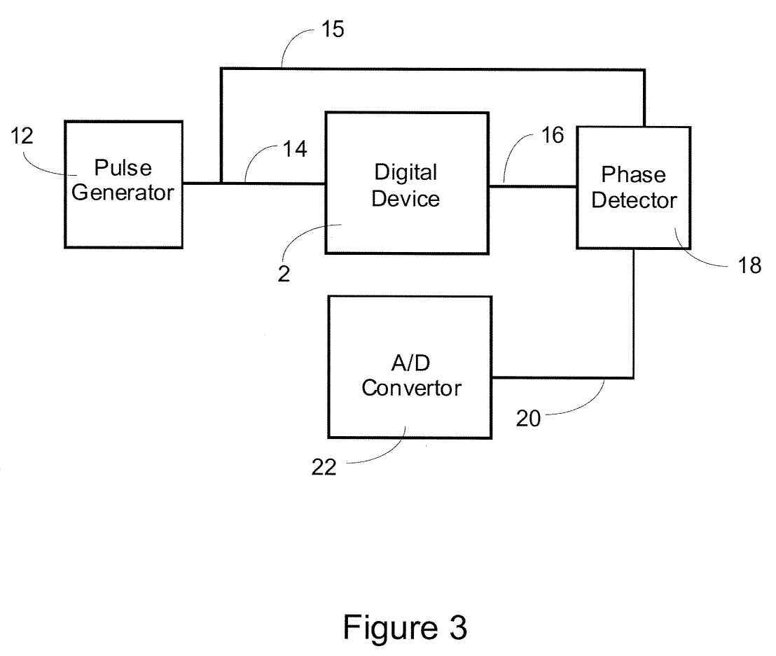

The signal comparator 18 can take on a variety of forms, depending on the nature of the test signal 16. FIG. 3 shows an example for a digital chip (this example is described in detail in “Dynamic Thermal Laser Signal Injection Microscopy (T-LSIM) on AC Propagation Failures, M. LaPierre and R. A. Falk, 43^{rd} IRPS, 280-285 [2005]). The drive source 12 in this example is a digital clock (pulse generator) that produces the drive signal 14 shown in FIGS. 2A and 2B. FIG. 2A shows a test signal 16, which is defined as perfect. FIG. 2B shows a test signal 16, which is clearly imperfect. Imperfection in this case defined as both a rounding of the square wave in the perfect signal and a significant time delay between the drive signal 14 and the test signal 16. The amount of time (phase) delay between the two signals was chosen as the measure of perfection in this case and an implementation of the signal comparator 18 chosen to measure the quality of the test signal 18.

FIG. 3 shows a block diagram of showing how a signal comparator 18 can be implemented for this case. The signal comparator 18 is realized as a simple phase comparator (phase detector), which produces an output voltage proportional to the phase (time) delay between two inputs. This output voltage is the comparison signal 20. A pulse generator or clock produces a repetitive pulse that is used for both the drive signal 14 and the reference signal 15. This reference signal 15 and the test signal 16 illustrated in FIGS. 2A and 2B are used as the two inputs to the phase comparator. Since the comparison signal 20 is a simple analog voltage, the processing and display means 22 includes an analog to digital (A/D) converter to produce a digital signal that can be displayed on a computer and monitor.

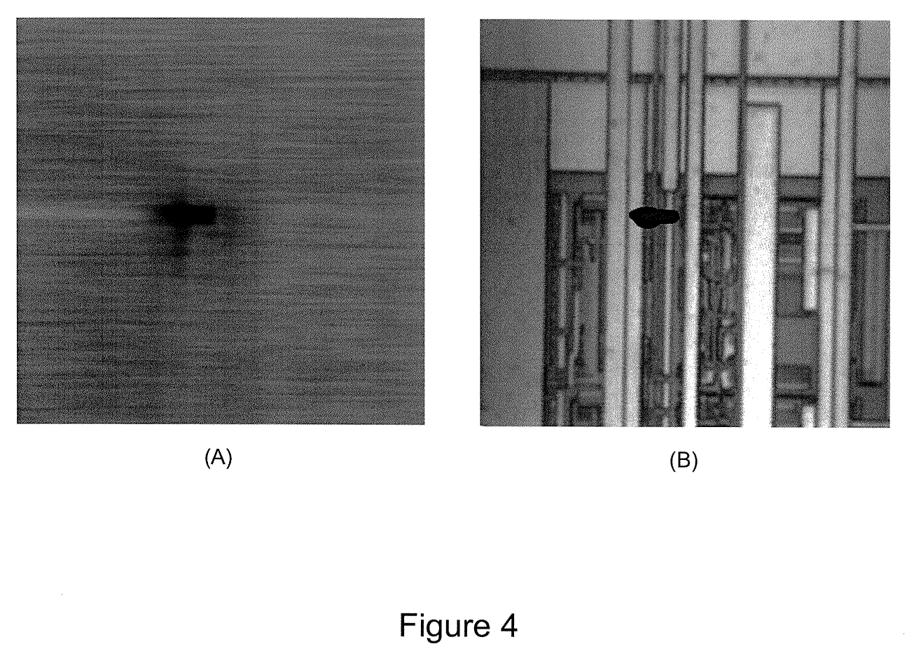

A laser scanning, confocal imaging system as described above was used to supply the remaining components of this embodiment of the invention. As the laser is scanned over the defect that is causing the unwanted time delay, its impedance changes, which causes a change in the phase delay. The time delay is recorded at the laser is scanned, producing a time delay map of the device. An example image/map obtained using this technique is shown in FIG. 4A. An increase in the time delay is represented as a white signal and a decrease in the time delay is represented as a dark signal. In this example, the signal is dark, indicating a decrease in the time delay. FIG. 4B shows an overlay of the darkest regions of the image/map of the comparison signal in FIG. 4A onto a simultaneously acquired confocal image. This overlay is produced by standard techniques of thresholding out the less dark areas of the image in FIG. 4A and electronically superimposing them onto the reference image. The information in these images allowed location of a defective via in the test structure 2 and correction of the fabrication process that caused the defect.

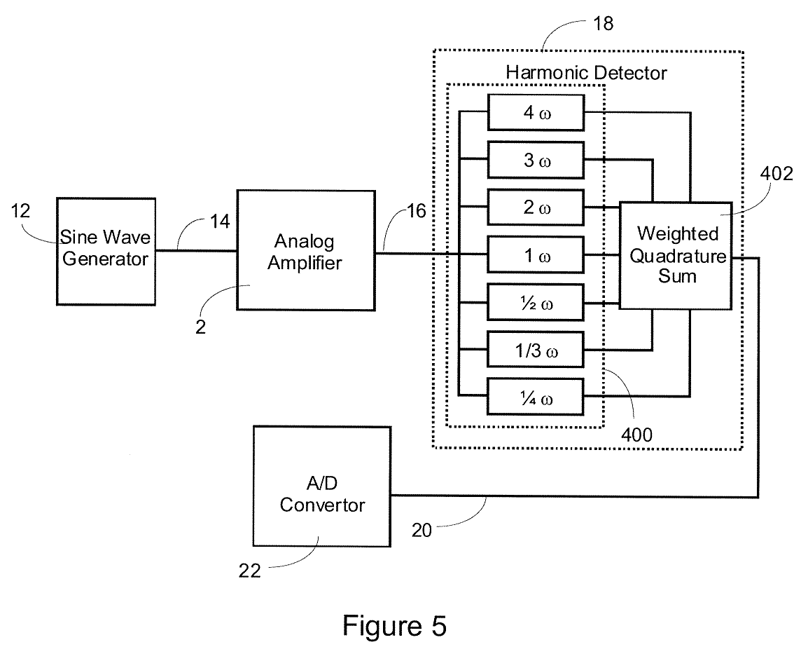

FIG. 5 shows the block diagram of another example embodiment. An important parameter of many amplifier circuits is how truly the output follows the input. One measure of this behavior is the generation of harmonic and sub-harmonic frequencies when a sine wave is amplified. For this implementation, the drive source 12 is a sine wave generator with frequency ω. The test structure 2 is an analog amplifier producing a test signal 16 that is a distorted representation of the input sine wave. The signal comparator 18 is a harmonic detector, whose purpose is to determine the power in the harmonics and sub-harmonics produced by the test structure 2 and to produce a comparison signal 20 that is related to the degree of distortion produced by the amplifier. Harmonic detectors can be produced in several forms. One form is shown in FIG. 5 which includes a bank of band pass filters 400, each filter is set to pass energy at a main frequency w, a set of harmonics ( 1/2ω, 1/3ω and ¼ω) and a set of sub-harmonics (½ω, ⅓ω and ¼ω). The outputs of these filters are passed to a weighted summer 402, which produces a comparison signal 20 proportional to the sum of the energies at the harmonics and sub-harmonics divided by the energy at the fundamental frequency, 0). This comparison signal 20 is passed to the processing and display means 22 similar to that described in the above example. Images/maps produced by this example will look similar to those in FIG. 4.

As can be seen, the basic form of the current invention can be implemented in a wide range of specific forms depending on the specific measures of the quality of the test signal 16 that are of importance to the tester. Examples of measures can be broken down into digital and analog measures as follows.

Digital measures of quality can include but are not limited to
Time or phase delay
Rise time
Fall time
Pulse duration
Repetition rate
Pattern matching

Analog measures of signal quality can include but are not limited to
Time or phase delay
Bandwidth
Upper and lower band pass
Harmonic and sub-harmonic generation
Linearity

Each of these measures have a variety of means by which the drive source 12, the drive signal 14, the reference signal 15, the test signal 16, the signal comparator 18 and the comparison signal can be implemented. Procedures for measuring each of the above listed parameters is known by those of ordinary skill in the art.

While the preferred embodiment of the invention has been illustrated and described, as noted above, many changes can be made without departing from the spirit and scope of the invention. Accordingly, the scope of the invention is not limited by the disclosure of the preferred embodiment. Instead, the invention should be determined entirely by reference to the claims that follow.

What is claimed is:

1. An apparatus for sensing dynamic failures in an electronic circuit, the apparatus comprising:
a) a drive source configured to supply a dynamic input signal to the electronic circuit, thereby causing the electronic circuit to output a signal;
b) a radiant energy source configured to generate and direct radiant energy at the electronic circuit and thus induce localized changes in said output signal of the electronic circuit; and
c) a signal comparator configured to compare the output signal to an expected output signal, thereby producing a comparison signal proportional to the match between the input and output signals, the comparison signal indicates existence of one or more type of dynamic failure in the electronic circuit.

2. The apparatus of claim 1, further comprising:
d) a data processing device configured to generate an image based on the comparison signal; and
e) a display device configured to display the generated image.

3. The apparatus of claim 2, further comprising:
f) a sensor configured to produce a reflection signal based on a reflection of the directed radiant energy,
wherein the data processing device is further configured to generate an image based on the reflection signal and the display device is further configured to display the reflection signal image.

4. The apparatus of claim 3, wherein the data processing device is further configured to extract one or more portions of the comparison signal image and superimpose the extracted one or more portions on the reflection signal image based on location information associated with the reflection signal image and the comparison signal image.

5. The apparatus of claim 4, wherein the extracted one or more portions indicate dynamic failures.

6. The apparatus of claim 1, wherein the comparison signal indicates a measure of quality of the electronic circuit.

7. The apparatus of claim 1, wherein the electronic circuit includes an amplifier circuit and the signal comparator includes:
a plurality of filters configured to filter the signal outputted by the amplifier circuit at a main frequency, at one or more harmonics of the main frequency and at one or more subharmonics of the main frequency; and
a component configured to produce the comparison signal based on the outputs of the plurality of filters.

8. The apparatus of claim 1, further comprising:
a scanning device configured to scan the radiant energy over the electronic circuit.

9. A method for sensing dynamic failures in an electronic circuit, the method comprising:
supplying a dynamic input signal to the electronic circuit, thereby causing the electronic circuit to output a signal;
generating and direct radiant energy at the electronic circuit and thus induce localized changes in said output signal of the electronic circuit; and
comparing the output signal to an expected output signal, thereby producing a comparison signal proportional to the match between the input and output signals, the comparison signal indicates existence of one or more type of dynamic failure in the electronic circuit.

10. The method of claim 9, further comprising:
generating an image based on the comparison signal; and
displaying the generated image.

11. The method of claim 10, further comprising:
producing a reflection signal based on a reflection of the directed radiant energy;
generating an image based on the reflection signal; and
displaying the generated reflection signal image.

12. The method of claim 11, further comprising:
extracting one or more portions of the comparison signal image; and
superimposing the extracted one or more portions on the reflection signal image based on location information associated with the reflection signal image and the comparison signal image.

13. The method of claim 12, wherein the extracted one or more portions indicate dynamic failures.

14. The method of claim 9, wherein the comparison signal indicates a measure of quality of the electronic circuit.

15. The method of claim 9, wherein comparing includes:
filtering the signal outputted by the amplifier circuit at a main frequency, at one or more harmonics of the main frequency and at one or more subharmonics of the main frequency; and
producing the comparison signal based on the outputs of the plurality of filters.

16. The method of claim 9, further comprising:
scanning the radiant energy over the electronic circuit.
